(19) United States
(12) Patent Application Publication
(10) Pub. No.: US 2017/0141259 A1
(43) Pub. Date: May 18, 2017

(54) NITRIDE SEMICONDUCTOR WAFER AND MANUFACTURING METHOD THEREOF

(71) Applicant: SUMITOMO CHEMICAL COMPANY, LIMITED, Tokyo (JP)

(72) Inventor: Hajime FUJIKURA, Ibaraki (JP)

(73) Assignee: SUMITOMO CHEMICAL COMPANY, LIMITED, Tokyo (JP)

(21) Appl. No.: 15/418,148

(22) Filed: Jan. 27, 2017

Related U.S. Application Data
(63) Continuation of application No. PCT/JP2015/070863, filed on Jul. 22, 2015.

(30) Foreign Application Priority Data
Jul. 29, 2014 (JP) 2014-154058

(51) Int. Cl. H01L 33/00; H01L 33/06; H01L 33/32; H01L 33/02

(52) U.S. Cl. CPC H01L 33/007; H01L 33/025; H01L 33/06; H01L 33/32

(57) ABSTRACT

Provided is a nitride semiconductor wafer in which, above a nitride semiconductor template having a nitride semiconductor layer as a top layer thereof, a light emitting layer having a multiple quantum well structure that is formed by a regrown nitride semiconductor and a p-type nitride semiconductor layer are stacked. Here, when the light emitting layer having a multiple quantum well structure includes a plurality of well layers and one of the well layers that is the closest to the p-type nitride semiconductor layer is referred to as a top well layer, a distance t from a regrowth interface of the nitride semiconductor layer of the nitride semiconductor template to the top well layer is 1 μm or less, and the top well layer has an oxygen concentration of 5.0×10¹⁶ cm⁻³ or less.

The contents of the following Japanese patent applications(s) are incorporated herein by reference:
No. 2014-154058 filed in JP on Jul. 29, 2014, and
No. PCT/JP2015/070863 filed on Jul 22, 2015.

### BACKGROUND

1. Technical Field

The present invention relates to a nitride semiconductor wafer and a method of manufacturing the same.

2. Related Art

Nitride semiconductors such as GaN, AlGaN and GaInN attract attention as they can be used to manufacture light emitting elements capable of emitting light having a wide range of wavelengths from red to ultraviolet. Nitride semiconductor light emitting elements (hereinafter, may be simply referred to as “light emitting elements”) such as light emitting diodes (LEDs) made of the above-mentioned nitride semiconductors can be fabricated by device processing on nitride semiconductor wafers. A nitride semiconductor wafer can be formed, for example, by sequentially growing, on a substrate, a nitride semiconductor layer (for example, a n-type GaN layer) and a light emitting section (for example, a light emitting layer) (see, for example, Japanese Patent Application Publication No. 2002-280611).

A nitride semiconductor wafer can be manufactured from scratch by using a substrate, or using a so-called nitride semiconductor template including a substrate and a nitride semiconductor layer grown on the substrate (hereinafter, may be simply referred to as “a template”). The manufacturing method using a template can achieve a reduced number of steps since the template can be purchased and a nitride semiconductor wafer can be obtained by growing a light emitting section on the nitride semiconductor layer of the template, for example.

Here, it is important for the light emitting element fabricated using the nitride semiconductor wafer that excellent light emission efficiency is achieved. The light emission efficiency of the light emitting elements is determined by the crystallinity of the light emitting section. As the crystallinity increases, the light emission efficiency rises. Generally speaking, the crystallinity of the light emitting section is dependent on the crystallinity of the nitride semiconductor layer of the template on which the light emitting section is grown. In other words, if the nitride semiconductor layer has low crystallinity, the light emitting section grown on the nitride semiconductor layer may also suffer from low crystallinity. Accordingly, the nitride semiconductor layer of the template is required to have high crystallinity in order to achieve excellent light emission characteristics for the light emitting element.

In the template, the nitride semiconductor layer is generally grown thick in order to accomplish improved crystallinity for the nitride semiconductor layer. The nitride semiconductor layer has a thickness of approximately 10 μm, for example. The nitride semiconductor layer is grown by metalorganic vaper phase epitaxy (MOVPE) or hydride vapor phase epitaxy (HYPE). When MOVPE is used, however, the growth rate is slow or several μm/hr. Therefore, a long time may be taken to grow a generally thick nitride semiconductor layer and the manufacturing cost may be high. For this reason, the nitride semiconductor layer is grown using HYPE, which can generally achieve a higher growth rate than MOVPE or a growth rate of 10 μm/hr or more, or 100 μm/hr or more.

A nitride semiconductor wafer can include a light emitting section having excellent crystallinity if the light emitting section is grown again (i.e., regrown) on a template that has been formed using, for example, HYPE. To form the light emitting section, for example, an n-type semiconductor layer made of a nitride semiconductor, a light emitting layer having a multiple quantum well structure and a p-type semiconductor layer are formed in the stated order on the template. The light emitting layer having a multiple quantum well structure has a laminate structure in which barrier layers and well layers are alternately grown. In the light emitting layer having a multiple quantum well structure, the well layer the closest to the p-type semiconductor layer, that is to say, the well layer at the top of the laminate structure (hereinafter, may be referred to as the top well layer) emits the strongest light. The top well layer has great influence on the light emission characteristics of the light emitting element.

The top well layer in the light emitting layer is formed above the nitride semiconductor layer of the template with the n-type semiconductor layer and the barrier and well layers placed therebetween. In other words, the top well layer is distant by a predetermined distance t from the growth surface of the nitride semiconductor layer. The distance t is equivalent to the thickness of the grown films (i.e., the growth thickness) from the growth surface of the template on which the light emitting section is to be regrown (hereinafter, may be referred to as the regrowth interface) to the top well layer of the light emitting layer. In conventional nitride semiconductor wafers, the distance t was approximately 2 μm or more in order to achieve predetermined light emission characteristics.

In recent years, attempts have been made to further improve the productivity of and reduce the cost of manufacturing the nitride semiconductor wafers. To reach these goals, there is a demand to reduce the distance t of the nitride semiconductor wafers in order to reduce the thickness. The growth thickness may be reduced by, for example, reducing the thickness of the n-type semiconductor layer positioned lower than the top well layer of the light emitting layer. Alternatively, it may be contemplated to reduce the thickness of the light emitting layer by reducing the number of pairs of the barrier layer and the well layer in the light emitting layer having a multiple quantum well structure.

However, when the distance t from the regrowth interface of the template to the top well layer of the light emitting layer is set to approximately 1μm or less, such a nitride semiconductor wafer could not produce light emitting elements having sufficient light emission characteristics.

The present invention is made in light of the above-described problems. The objective of the present invention is to provide a nitride semiconductor wafer that can produce a light emitting element having a small growth thickness, excellent productivity and sufficient light emission characteristics and a method of manufacturing the same.

As described above, if the distance t from the regrowth interface of the template to the top well layer of the light emitting layer in the nitride semiconductor wafer is short, the nitride semiconductor wafer cannot produce a light emitting element having sufficient light emission characteristics. The inventors of the present invention examined this problem and found that the nitride semiconductor wafers cannot achieve sufficient light emission characteristics because impurities such as oxygen inevitably enter the light emitting section and the like during the manufacturing process thereof.

The following describes the process of manufacturing the nitride semiconductor wafers and the oxygen that may enter the nitride semiconductor wafers during the manufacturing process thereof.

As described above, a nitride semiconductor wafers is manufactured in such a manner that a template is first formed by growing a nitride semiconductor layer on a substrate using HVPE and a light emitting section (for example, a light emitting layer having a multiple quantum well structure, and the like) is subsequently regrown on the template using MOVPE. Specifically speaking, to start with, the template is formed by growing a nitride semiconductor layer on a substrate in a HVPE apparatus. Subsequently, the formed template is unloaded out of the HVPE apparatus and loaded into a MOVPE apparatus. In the MOVPE apparatus, a light emitting section and the like are grown again (i.e., regrown) on the template. In this manner, a nitride semiconductor wafer is manufactured. As is apparent from the above, when the nitride semiconductor wafer is manufactured using the template, the nitride semiconductor layer and the light emitting section are grown using different growing techniques instead of employing the same growing technique to continuously grow them (i.e., the continuous growth technique). As used herein, the term “to regrow” and its derivatives indicate that the light emitting section is regrown again after the nitride semiconductor layer is grown, and not only represents the above-described case where different growing techniques are employed but also represents a case where, for example, the template is stored for a predetermined period of time and the light emitting section is grown again on the template.

When the nitride semiconductor wafer is manufactured using the template, the template is accordingly transported from the HVPE apparatus to the MOVPE apparatus since the continuous growth technique is not employed. During the transport, the template is exposed to the atmosphere and oxidized. As a result, an oxide film is formed on the growth surface of the nitride semiconductor layer of the template (i.e., the regrowth interface). Since the oxide film is formed, the regrowth interface of the template exhibits a high oxygen concentration.

If the light emitting section is regrown on the template on which the oxide film has been formed, the light emitting section is regrown on the nitride semiconductor layer with the oxide film placed therebetween. This causes the oxygen contained in the oxide film (for example, oxygen atoms) to diffuse into the light emitting section during the regrowth. Specifically speaking, in the MOVPE apparatus, the light emitting section (for example, the n-type semiconductor layer and the light emitting layer having a multiple quantum well structure) is formed in such a manner that a film is gradually regrown in the heated environment of approximately 600° C. to 1000° C. to increase the thickness. During the regrowth, the oxide film is also heated, which activates the oxygen contained in the oxide film. The activated oxygen gradually diffuses from the oxide film into the regrown n-type semiconductor layer, the light emitting layer having a multiple quantum well structure and the like and eventually enters the light emitting section.

If the entrance of the oxygen into the light emitting section results in a high oxygen concentration in the light emitting section, the light emission characteristics of the light emitting section tend to be compromised. In particular, if the oxygen enters the top well layer, which greatly influences the light emission characteristics, and results in a high oxygen concentration in the top well layer, the light emission characteristics significantly drop.

Conventionally, the distance t from the regrowth interface of the template to the top well layer was set to approximately 2 μm or more as described above, or a thick film was regrown. In other words, the n-type semiconductor layer and the light emitting layer excluding the top well layer, which are regrown on the template, had a total thickness of approximately 2 μm or more. For this reason, in the conventional art, the oxygen may have diffused from the oxide film to the n-type semiconductor layer and the light emitting layer in order, but was unlikely to reach the top well layer of the light emitting layer. Therefore, the light emission characteristics were prevented from significantly dropping.

On the other hand, when the distance t was reduced to 1μm or less and a thin film was regrown, the oxygen diffusing from the oxide film and entered the top well layer. This resulted in a significant drop in light emission characteristics. The distance t is reduced by, for example, reducing the thickness of the n-type semiconductor layer or reducing the number of pairs of the barrier layer and the well layer to reduce the thickness of the light emitting layer.

As discussed above, in the nitride semiconductor wafer manufactured using the template, the oxygen introduced during the manufacturing process diffused to the top well layer of the light emitting layer during the regrowth, which resultantly lowered the light emission characteristics. For this reason, when the nitride semiconductor wafer was manufactured using the template, it was difficult to reduce the growth thickness and to achieve high light emission characteristics at the same time.

In light of the above, the inventors of the present invention thought that it must have been important to know how far the diffusing oxygen travels (hereinafter, may be referred to as the diffusion distance) in order to reduce the growth thickness and achieve high light emission characteristics at the same time. To be specific, the inventors assumed that, if the distance t from the regrowth interface of the template to the top well layer is equal to or longer than the diffusion distance of the oxygen (or the diffusion distance of the oxygen that produces such an oxygen concentration that adversely affects the light emission characteristics), the diffusing oxygen may have traveled through the light emitting layer having a multiple quantum well structure but did not reach the top well layer (or did not produce such an oxygen concentration that the light emission characteristics were adversely affected) and the light emission characteristics could be prevented from dropping. In addition, if the growth thickness can be controlled in accordance with the diffusion distance of the oxygen, the growth thickness can be prevented from unnecessarily increasing. For the reasons stated above, the inventors concluded that this technical idea could achieve a reduced growth thickness and improved productivity for the nitride semiconductor wafer manufacturing process.

It is known that the diffusion distance of the oxygen is greatly dependent on the growth temperature during the regrowth, in particular, the maximum value of the growth temperature T_{MAX}. In other words, as the maximum value of the growth temperature T_{MAX} rises, the oxygen tends to diffuse further and the diffusion distance of the oxygen thus increases. Note that, although the diffusion distance of the oxygen is known to be dependent on the temperature, it is difficult to accurately know the diffusion distance of the oxygen.

Therefore, the inventors of the present invention attempted to obtain the minimum distance tₘᵢₙ that can prevent the drop in the light emission characteristics of the light emitting element caused by the diffusion and entrance of the oxygen into the top well layer, which is equivalent to the theoretical value of the diffusion distance of the oxygen. Here, the drop in the light emission characteristics means that the light emitted by the light emitting element manufactured using a nitride semiconductor wafer of an embodiment of the present invention fabricated using a template when 20 mA is applied is less than 50% of the light emitted by a light emitting element having the same structure and fabricated using the continuous growth technique when 20 mA is applied.

The inventors of the present invention examined the correlation between the diffusion distance of the oxygen and the temperature in order to obtain the minimum distance tₘᵢₙ, which was equivalent to the theoretical value of the diffusion distance of the oxygen. The diffusion of the oxygen means the movement of oxygen atoms by overcoming the barrier energy Eₐ which corresponds to the activation energy for oxygen atoms to diffuse within the nitride semiconductor layer. The distance by which the oxygen moves is considered to be the diffusion distance of the oxygen. The diffusion distance of the oxygen is determined by the diffusion constant of the oxygen atoms, and the diffusion distance increases as the diffusion constant increases. The diffusion constant of the oxygen atoms is considered to be expressed by an expression A×exp(−Eₐ/kT), where T denotes the temperature and Eₐ denotes the barrier energy required to diffuse the oxygen. In the expression , A denotes a constant and k denotes the Boltzmann's constant. According to the expression, the diffusion constant of the oxygen (i.e., the diffusion distance of the oxygen) is dependent on the temperature T and the so-called Arrhenius relation is true between the diffusion constant of the oxygen and the temperature T.

Therefore, the inventors of the present invention made an Arrhenius plot based on the minimum distance tₘᵢₙ, which is equivalent to the theoretical value of the diffusion distance of the oxygen, and the maximum value of the growth temperature T_{MAX}, and obtained the expression expressing the relation between the maximum value of the growth temperature T_{MAX} and the minimum distance tₘᵢₙ based on the Arrhenius plot. The inventors discovered that, when a light emitting section was actually regrown, the oxygen could be prevented from entering the top well layer of the light emitting layer by setting the distance t from the regrowth interface of the template to the top well layer of the light emitting layer equal to or longer than the minimum distance tₘᵢₙ calculated by a predetermined expression (i.e., the theoretical value of the diffusion distance of the oxygen). In addition, the inventors discovered that, by lowering the oxygen concentration in the top well layer to fall within a predetermined range of concentrations, the resulting nitride semiconductor wafer could be manufactured into a light emitting element having sufficient light emission characteristics. On top of this, the inventors discovered that the growth thickness could be reduced and the productivity could be thus improved since the regrowth could be regulated in accordance with the diffusion distance of the oxygen or the minimum distance tₘᵢₙ that does not compromise the light emission characteristics of the resulting light emitting element.

The present invention is made based on the above-described findings and described in the following.

### SUMMARY

A first aspect of the present invention provides a nitride semiconductor wafer in which, above a nitride semiconductor template having a nitride semiconductor layer as a top layer thereof, a light emitting layer having a multiple quantum well structure that is formed by a regrown nitride semiconductor and a p-type nitride semiconductor layer are stacked. Here, when the light emitting layer having a multiple quantum well structure includes a plurality of well layers and one of the well layers that is the closest to the p-type nitride semiconductor layer is referred to as a top well layer, a distance t from a regrowth interface of the nitride semiconductor layer of the nitride semiconductor template to the top well layer is 1 μm or less, and the top well layer has an oxygen concentration of 5.0×10¹⁶ cm⁻³ or less.

A second aspect of the present invention provides the nitride semiconductor wafer of the first aspect, where the distance t is 500 nm or less.

A third aspect of the present invention provides the nitride semiconductor wafer of the first or second aspect, further including an n-type nitride semiconductor layer between the nitride semiconductor layer and the light emitting layer having a multiple quantum well structure.

A fourth aspect of the present invention provides the nitride semiconductor wafer of the first or second aspect, where the light emitting layer having a multiple quantum well structure is positioned immediately above the nitride semiconductor layer.

A fifth aspect of the present invention provides a method of manufacturing a nitride semiconductor wafer in which, above a nitride semiconductor template having a nitride semiconductor layer as a top layer thereof, a light emitting layer having a multiple quantum well structure that is formed by a regrown nitride semiconductor and a p-type nitride semiconductor layer are stacked. The method includes above the nitride semiconductor layer of the nitride semiconductor template, regrowing in order the light emitting layer having a multiple quantum well structure and the p-type nitride semiconductor layer. Here, when the light emitting layer having a multiple quantum well structure includes a plurality of well layers and one of the well layers that is the closest to the p-type nitride semiconductor layer is referred to as a top well layer, the regrowing is performed in such a manner that a distance t [nm] from a regrowth interface of the nitride semiconductor layer of the nitride semiconductor template to the top well layer and a maximum value of a growth temperature T_{MAX} [° C.] for the regrowth satisfy a relation expressed by t≧3.682×10⁶ ×exp{−Eₐ/k(T_{MAX}+273)} and the distance t is 1 μm or less, where Eₐ is set to 0.915 [eV] and k denotes the Boltzmann's constant.

### Effects of the Invention

The present invention can provide a nitride semiconductor wafer that has a small growth thickness, excellent productivity and can be used to fabricate a light emitting element having sufficient light emission characteristics.

### BRIEF DESCRIPTION OF THE DRAWINGS

FIG. 1 is a cross-sectional view showing a nitride semiconductor wafer relating to one embodiment of the invention as set forth herein.

FIG. 2 shows the correlation between the maximum value of the growth temperature T_{MAX} and the distance tₘᵢₙ during regrowth.

### EXEMPLARY EMBODIMENTS OF THE INVENTION

### One Embodiment of the Invention as Set Forth Herein

The following describes one embodiment of the invention as set forth herein.

(1) Nitride Semiconductor Wafer

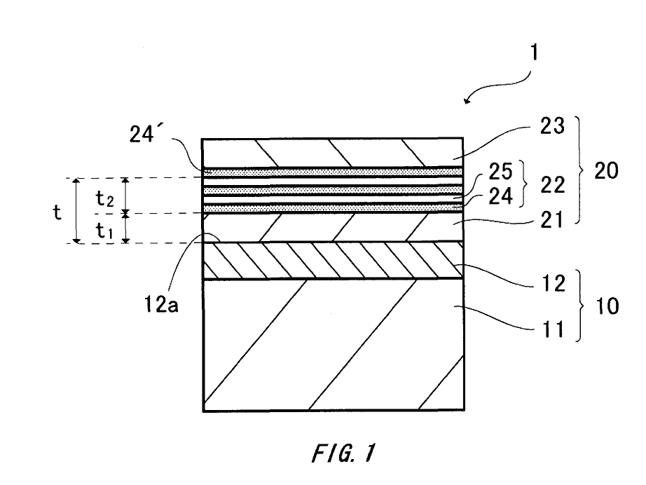

To start with, a nitride semiconductor wafer relating to one embodiment is described with reference to FIG. 1. FIG. 1 is a cross-sectional view showing a nitride semiconductor wafer relating to one embodiment of the invention as set forth herein.

A nitride semiconductor wafer 1 relating to the present embodiment is formed using a nitride semiconductor template 10 having a substrate 11 and a nitride semiconductor layer 12 grown on the substrate 11, and more specifically, manufactured by regrowing a light emitting section 20 on the nitride semiconductor layer 12. In other words, the nitride semiconductor layer 12 and the light emitting section 20 are not formed using the continuous growth technique but formed separately by growing the nitride semiconductor layer 12 and subsequently regrowing the light emitting section 20.

In the nitride semiconductor wafer 1 relating to the present embodiment, as shown in FIG. 1, on the nitride semiconductor template 10 having the nitride semiconductor layer 12 as the top layer thereof (hereinafter, may be simply referred to as “the template 10”), a n-type nitride semiconductor layer 21, a light emitting layer 22 having a multiple quantum well structure and a p-type nitride semiconductor layer 23 are regrown in the stated order as the light emitting section 20.

The template 10 is manufactured by growing a nitride semiconductor on the substrate 11 and structured in such a manner that the substrate 11 and the nitride semiconductor layer 12 are stacked.

The substrate 11 is not particularly limited as long as it can be formed by growing the nitride semiconductor layer 12 on the surface thereof. The substrate 11 can be, for example, a sapphire substrate, a ZnO substrate, a SiC substate, a Si substrate, a GaAs substrate, a GaN substrate, a AlN substrate, a AlGaN substrate or the like. From among these, a sapphire substrate is preferable. More specifically, a patterned sapphire substrate (PSS) that is obtained by forming projections and depressions on the surface of a sapphire substrate is preferably used for LEDs.

The nitride semiconductor layer 12 is formed on the substrate 11 and has a regrowth interface 12a on which the light emitting section 20 is regrown. The nitride semiconductor layer 12 is made of, for example, gallium nitride (GaN), aluminum nitride (AlN), aluminum gallium nitride (AlGaN), indium aluminum gallium nitride (InAlGaN) or the like. In addition, a buffer layer may be provided between the substrate 11 and the nitride semiconductor layer 12. The buffer layer is, for example, a GaN or AlN layer grown at low temperature, an AlN layer grown at high temperature, or the like. The nitride semiconductor layer 12 may contain n-type impurities such as silicon (Si) and germanium (Ge), or may be a n-type semiconductor layer. The amount of the n-type impurities contained is selected as appropriate in accordance with how the template is used or depending on other factors.

The thickness of the nitride semiconductor layer 12 is not particularly limited and can be, for example, no less than 2 μm and no more than 50 μm. The nitride semiconductor layer 12 achieves improved crystallinity due to having a predetermined thickness and contributes to improve the crystallinity of the light emitting section 20 to be regrown on the regrowth interface 12a. The technique used to grow the nitride semiconductor layer 12 is not particularly limited. The HVPE technique, which exhibits a high growth rate, is preferable but the MOVPE technique or the like can be also used. As described above, the regrowth interface 12a is oxidized when the template 10 is exposed to the air and has an oxide film (not shown) foil led thereon.

The light emitting section 20 is formed by regrowth on the regrowth interface 12a of the nitride semiconductor layer 12. In the present embodiment, as the light emitting section 20, the n-type nitride semiconductor layer 21 made of a nitride semiconductor, the light emitting layer 22 having a multiple quantum well structure and the p-type nitride semiconductor layer 23 are regrown in the stated order. The light emitting section 20 is grown using MOVPE, which can form a thin semiconductor layer of several nanometers under great controllability and can achieve excellent crystallinity.

The n-type nitride semiconductor layer 21 is formed on the regrowth interface 12a of the nitride semiconductor layer 12. As the n-type nitride semiconductor layer 21, an n-type GaN layer is grown, for example. The n-type nitride semiconductor layer 21 contains a predetermined concentration of predetermined n-type impurities. The n-type impurities can be, for example, silicon (Si), selenium (Se), tellurium (Te) and the like. The thickness of the n-type nitride semiconductor layer 21 is not particularly limited and can be, for example, no less than 0 μm and no more than 1 μm.

The light emitting layer 22 having a multiple quantum well structure has a laminate structure in which well layers 24 and barrier layers 25 are alternately grown on the n-type nitride semiconductor layer 21. In the laminate structure, one of the well layers 24 that is the closest to the p-type nitride semiconductor layer 23 is referred to as a top well layer 24′. The well layers 24 are, for example, InGaN layers and the barrier layers 25 are, for example, GaN layers. The thickness of each of the well layers 24 constituting the light emitting layer 22 can be, for example, no less than 1 nm and no more than 5 nm, and the thickness of each of the barrier layers 25 can be, for example, no less than 5 nm and no more than 30 nm. A plurality of pairs of the well layer 24 and the barrier layer 25 are formed to achieve desired light emission.

The p-type nitride semiconductor layer 23 is formed on the light emitting layer 22 having a multiple quantum well structure and above the top well layer 24′ of the light emitting layer 22 having a multiple quantum well structure. The p-type nitride semiconductor layer 23 is, for example, a p-type AlGaN layer or p-type GaN layer. As the p-type nitride semiconductor layer 23, a p-type AlGaN layer and a p-type GaN layer may be grown in the stated order on the regrowth interface 12a, for example. The p-type nitride semiconductor layer 23 contains a predetermined concentration of predetermined p-type impurities. The p-type impurities can be, for example, magnesium (Mg), zinc (Zn), carbon (C) or the like. The thickness of the p-type nitride semiconductor layer 23 is not particularly limited and can be, for example, no less than 200 nm and no more than 1000 nm.

In the nitride semiconductor wafer 1 relating to the present embodiment, by regrowing a nitride semiconductor on the regrowth interface 12a of the nitride semiconductor layer 12, the n-type nitride semiconductor layer 21, the light emitting layer 22 having a multiple quantum well structure and the p-type nitride semiconductor layer 23 are formed, as the light emitting section 20. The distance t from the regrowth interface 12a of the nitride semiconductor layer 12 to the top well layer 24′ of the light emitting layer 22 having a multiple quantum well structure is 1 μm or less. In other words, the sum of the thickness t₁ of the n-type nitride semiconductor layer 21 and the thickness t₂ of the light emitting layer 22 excluding the top well layer 24′ is equal to 1 μm or less. Preferably, the distance t is 500 nm or less, more preferably no less than 200 nm and no more than 500 nm. This can shorten the time required to grow the light emitting section 20 and improve the productivity of the manufacturing process of the nitride semiconductor wafer 1.

The top well layer 24′ of the light emitting layer 22 having a multiple quantum well structure has an oxygen concentration of 5.0×10⁶ cm⁻³ or less, which indicates that the amount of the oxygen introduced by the diffusion is reduced. For this reason, in the top well layer 24′, the degradation of the crystallinity is reduced, and the drop in the light emission characteristics is reduced.

Here, the oxygen concentration is measured in the thickness direction of the top well layer 24′ using, for example, secondary ion mass spectrometry (SIMS).

In the present embodiment, the thickness t₁ of the n-type nitride semiconductor layer 21 and the thickness t₂ of the light emitting layer 22 excluding the top well layer 24′ are not particularly limited and the thicknesses t₁ and t₂ can be changed as appropriate provided their sum is 1 μm or less.

(2) Method of Manufacturing Nitride Semiconductor Wafer

The following describes a method of manufacturing the above-described nitride semiconductor wafer 1. In the present embodiment, the template 10 is formed and the template 10 is then used to manufacture the nitride semiconductor wafer 1.

<Preparation of Substrate 11>

To start with, the substrate 11, for example a sapphire substrate is prepared.

<Growth of Nitride Semiconductor Layer 12>

Following this, the substrate 11, for example, the sapphire substrate is loaded into a HVPE apparatus. In the HVPE apparatus, a predetermined source gas is fed onto the substrate 11 or sapphire substrate to grow a GaN layer having a predetermined thickness (for example, no less than 2 μm and no more than 50 μm) as the nitride semiconductor layer 12. In this way, the template 10 is obtained.

<Transport of Template 10>

Subsequently, the template 10 is transported from the HVPE apparatus to a MOVPE apparatus. Alternatively, the template 10 may be stored for a predetermined period of time and then transported from the HVPE apparatus to a MOVPE apparatus. Since the template 10 is exposed to the air during the transport, the GaN layer of the nitride semiconductor layer 12 is oxidized and an oxide film is formed on the regrowth interface 12a of the nitride semiconductor layer 12.

<Regrowing Step of Light Emitting Section 20>

After this, in the MOVPE apparatus, a regrowing step is performed to regrow the light emitting section 20 on the nitride semiconductor layer 12. During the regrowing step, the regrowth is controlled in such a manner that the distance t [nm] from the regrowth interface 12a of the nitride semiconductor layer 12 to the top well layer 24′ and the maximum value of the growth temperature T_{MAX} [° C.] for the regrowth satisfy the following Expression (1) and the distance t can be 1 μm or less.

t≧tₘᵢₙ=3.682×10⁶×exp{−Eₐ/k(T_{MAX}+273)} (1)

In Expression (1), Eₐ is set to 0.915 [eV] and k denotes the Boltzmann's constant.

Specifically speaking, for the regrowing step, the conditions for growing the light emitting section 20 are determined based on Expression (1) and the light emitting section 20 is regrown based on the determined regrowth conditions. The following describes Expression (1) used to determine the growth conditions, how to determine the growth conditions based on Expression (1) and the regrowth of the light emitting section 20 based on the growth conditions.

(Expression (1))

Expression (1) is set up based on the Arrhenius plot between the minimum distance tₘᵢₙ that does not cause the drop in the light emission characteristics of the light emitting element and the maximum value of the growth temperature T_{MAX}, which are obtained through experiments (working examples described later).

In Expression (1), the distance t denotes the growth thickness from the regrowth interface 12a of the nitride semiconductor layer 12 to the top well layer 24′ of the light emitting layer 22. In other words, the distance t denotes the thickness of the grown film that is actually grown on the regrowth interface 12a until the top well layer 24′ is formed (the growth thickness). As shown in FIG. 1, when the n-type semiconductor layer 21, the light emitting layer 22 having a multiple quantum well structure and the p-type semiconductor layer 23 are formed as the light emitting section 20, the distance t is equal to the total of the thickness t₁ of the n-type nitride semiconductor layer 21 and the thickness t₂ of the light emitting layer 22 excluding the top well layer 24′ (t=t₁ +t₂).

In Expression (1), the distance t₁, denotes the minimum distance that does not cause the drop in the light emission characteristics of the light emitting element and is equivalent to the theoretical value of the diffusion distance of the oxygen at a predetermined temperature. The minimum distance tₘᵢₙ can be obtained based on the Arrhenius plot against the maximum value of the growth temperature T_{MAX} as described above. In other words, as indicated in Expression (1), the minimum distance tₘᵢₙ is a function of the maximum value of the growth temperature T_{MAX} and can be calculated from the maximum value of the growth temperature T_{MAX}.

In Expression (1), the maximum value of the growth temperature t_{MAX} denotes the highest one of the growth temperatures at which the respective layers of the light emitting section 20 are grown. The growth temperatures for the respective layers of the light emitting section 20 range as follows, for example. The growth temperature for the n-type nitride semiconductor layer 21 is no less than 800° C. and no more than 1000° C., the growth temperature for the light emitting layer 22 is no less than 600° C. and no more than 900° C., and the growth temperature for the p-type nitride semiconductor layer 23 is no less than 700° C. and no more than 1000° C. Therefore, the maximum value of the growth temperature T_{MAX} is at least 800° C. On the other hand, the maximum value of the growth temperature T_{MAX} is at most 1000° C. If the maximum value of the growth temperature T_{MAX} is higher than 1000° C., the diffusion of the oxygen is further encouraged and the distance tₘᵢₙ exceeds 1 μm. Therefore, when the maximum value of the growth temperature T_{MAX} is higher than 1000° C., it is difficult to achieve a distance t of 1 μm or less.

(How to Determine Growth Conditions)

Based on the above-described Expression (1), the conditions under which the light emitting section 20 is regrown are determined. In order to determine the growth conditions, the maximum value of the growth temperature T_{MAX} for the regrowth is first determined. Subsequently, the distance tₘᵢₙ corresponding to the determined maximum value of the growth temperature T_{MAX} is calculated based on Expression (1). The calculated distance tₘᵢₙ is used to determine the distance t.

Specifically speaking, the maximum value of the growth temperature T_{MAX} is first determined. The maximum value of the growth temperature T_{MAX} is determined by the growth temperatures for the respective layers of the light emitting section 20. The light emitting section 20 is constituted by the n-type nitride semiconductor layer 21, the light emitting layer 22 and the p-type nitride semiconductor layer 23, and the growth temperatures for the respective layers are selected as appropriate within the predetermined range of temperatures. From among the growth temperatures for the respective layers, the maximum temperature is treated as the maximum value of the growth temperature T_{MAX}.

Subsequently, the distance tₘᵢₙ is obtained in accordance with the determined maximum value of the growth temperature T_{MAX}. The distance tₘᵢₙ is calculated by substituting the determined maximum value of the growth temperature T_{MAX} into Expression (1). As mentioned above, the distance tₘᵢₙ is equivalent to the theoretical value of the diffusion distance of the oxygen at a predetermined temperature and indicates the minimum distance that does not cause the drop in the light emission characteristics of the light emitting element.

Subsequently, the obtained distance tₘᵢₙ is used to determine the distance t. The distance t denotes the growth thickness of the films that are actually grown on the regrowth interface 12a up to the top well layer 24′, as described above. In the case shown in FIG. 1, the distance t is equal to the sum of the thickness t₁ of the n-type nitride semiconductor layer 21 and the thickness t₂ of the light emitting layer 22 excluding the top well layer 24′(t=t₁ +t₂). The thicknesses t₁ and t₂ can be respectively changed as appropriate, and the distance t can be changed as appropriate by setting the thicknesses t₁ and t₂ at predetermined numerical values. According to the present embodiment, when the maximum value of the growth temperature T_{MAX} takes a predetermined value, the distance t is determined to be equal to or longer than the obtained distance tₘᵢₙ (the distance t≧the distance tₘᵢₙ) in order to prevent the oxygen contained in the oxide film formed on the regrowth interface 12a from entering the top well layer 24′ as a result of the diffusion. In other words, the sum of the thickness t₁ of the n-type nitride semiconductor layer 21 and the thickness t₂ of the light emitting layer 22 excluding the top well layer 24′ is set to be equal to or larger than the distance tₘᵢₙ. If the distance t is set smaller than the distance tₘᵢₙ (the distance t<the distance t₁), the oxygen diffusing from the oxide film may enter the top well layer 24′, which may lower the light emission characteristics. The upper limit of the distance t is not particularly limited as long as the distance t is no less than the distance tₘᵢₙ and no more than 1 μm, but the distance t is preferably short considering the purpose of improving the productivity by reducing the growth thickness.

For example, the growth conditions are determined as follows. When the respective layers of the light emitting section 20 are regrown with the growth temperature of the n-type nitride semiconductor layer 21 set to 890° C., the growth temperature of the light emitting layer 22 set to 700° C. and the growth temperature of the p-type nitride semiconductor layer 23 set to 800° C., the maximum value of the growth temperature T_{MAX} is 890° C. Based on Expression (1), the distance tₘᵢₙ for this maximum value of the growth temperature T_{MAX} (890° C.) is calculated as 350 nm. Based on the calculated distance tₘᵢₙ (350 nm), the distance t is determined to be equal to or longer than 350 nm. Since the distance t is equal to the sum of the thickness t₁ of the n-type nitride semiconductor layer 21 and the thickness t₂ of the light emitting layer 22 excluding the top well layer 24′, the thicknesses t₁ and t₂ are respectively determined so that their sum (t₁ +t₂) is 350 nm or more. The thicknesses t₁ and t₂ are not particularly limited. For example, the thickness t₁ can be 200 nm and the thickness t₂ can be 150 nm. Since the thicknesses t₁ and t₂ can be respectively changed as appropriate so that their sum is equal to or larger than 350 nm, the thickness t₁ can be 50 nm and the thickness t₂ can be 300 nm.

(Regrowth of Light Emitting Section 20)

Subsequently, in the MOVPE apparatus, the light emitting section 20 is regrown under the growth conditions determined in the above-described manner. The light emitting section 20 is regrown at a growth temperature that does not exceed the maximum value of the growth temperature T_{MAX} determined as one of the growth conditions (for example, 890° C.).

A predetermined source gas is fed onto the regrowth interface 12a of the nitride semiconductor layer 12 to grow a n-type GaN layer having the thickness t₁ (for example, 200 nm) as the n-type nitride semiconductor layer 21. During the growth of this layer, the oxygen contained in the oxide film diffuses and enter the n-type nitride semiconductor layer 21.

Following this, a predetermined source gas is fed onto the n-type nitride semiconductor layer 21 to alternately grow InGaN layers as the well layers 24 and GaN layers as the barrier layers 25. As a result, the light emitting layer 22 having a multiple quantum well structure and a predetermined thickness is formed. During the growth of the light emitting layer 22, the top well layer 24′ starts to be grown once the sum of the thickness t₁ of the n-type nitride semiconductor layer 21 (for example, 200 nm) and the thickness t₂ of the light emitting layer 22 excluding the top well layer 24′(for example, 150 nm) reaches the distance tₘᵢₙ (for example, 350 nm) or more. In other words, the top well layer 24′ is foiled above the regrowth interface 12a with the n-type nitride semiconductor layer 21 and the light emitting layer 22 placed therebetween and positioned away from the regrowth interface 12a by the distance t (the thickness t₁ +the thickness t₂).

During the regrowth of the light emitting layer 22, the oxygen contained in the oxide film on the template diffuses, and the oxygen that has diffused and entered the n-type nitride semiconductor layer 21 further diffuses and enters part of the light emitting layer 22. According to the present embodiment, however, the top well layer 24′ is positioned away from the regrowth interface 12a by the distance tₘᵢₙ (the theoretical value of the diffusion distance of the oxygen at a predetermined temperature) or more, and the oxygen can be prevented from entering the top well layer 24′ as a result of the diffusion during the regrowing step.

Subsequently, a predetermined source gas is fed onto the top well layer 24′ of the light emitting layer 22 to grow and form a p-type GaN layer as the p-type nitride semiconductor layer 23. Although the oxygen may diffuse during the regrowth of the p-type nitride semiconductor layer 23, the oxygen is prevented from diffusing into the top well layer 24′ since the distance t is equal to or more than the distance tₘᵢₙ. As a result, the top well layer 24′ exhibits an oxygen concentration of 5.0×10¹⁶ cm⁻³ or less.

<Unloading of Nitride Semiconductor Wafer 1>

After the regrowing step, the nitride semiconductor wafer 1 is unloaded out of the MOVPE apparatus and the nitride semiconductor wafer 1 of the present embodiment can be obtained.

### Effects Produced by the Present Embodiment

The present embodiment produces the following one or more effects.

According to the present embodiment, in the nitride semiconductor wafer, the distance t from the regrowth interface to the top well layer is 1 μm or less, and the top well layer exhibits an oxygen concentration of 5.0×10¹⁶ cm⁻³ or less. Thus, the growth thickness is small and the productivity is high. The top well layer, which greatly influences the light emission characteristics, exhibits a low oxygen concentration. This means that the drop in the light emission characteristics caused by the entrance of the oxygen into the top well layer is prevented.

According to the present embodiment, the light emitting section is regrown in such a manner that the distance t from the regrowth interface to the top well layer and the maximum value of the growth temperature T_{MAX} for the regrowth satisfy a predetermined relation and that the distance t is 1 μm or less. As a result, when the light emitting section is regrown on the template, the oxygen can be prevented from diffusing into the top well layer, which greatly influences the light emission characteristics. In addition, since the growth temperature can determine the minimum distance (the growth thickness) that does not cause the drop in the light emission characteristics, the regrowing step is performed according to the thus determined growth thickness, which can resultantly reduce the growth thickness and improve the productivity.

### Other Embodiments

One embodiment of the invention as set forth herein has been specifically described. The invention as set forth herein, however, is not limited to the above-described embodiment, which can be modified in various manners without departing from the principle of the invention as set forth herein.

According to the above-described embodiment, the nitride semiconductor wafer further includes the n-type nitride semiconductor layer between the nitride semiconductor layer and the multiquantum well layer. The present invention, however, is not limited to such. According to the present invention, the light emitting layer may be provided immediately above the nitride semiconductor layer of the template without the n-type nitride semiconductor layer. In other words, the thickness t₁ of the n-type nitride semiconductor layer may be set to 0 and only the light emitting layer may be formed. In this case, the thickness t₂ of the light emitting layer excluding the top well layer is set to be equal to or larger than the distance tₘᵢₙ.

According to the above-described embodiment, the fabrication of the template by performing a growing step using HVPE is followed by a regrowing step using MOVPE in the manufacturing process of the the nitride semiconductor wafer. The present invention, however, is not limited to such. According to the present invention, the drop in the light emission characteristics caused by the diffusion of the oxygen can be prevented even if, for example, MOVPE is used to fabricate the template, the template is then unloaded, and MOVPE is again used to manufacture the nitride semiconductor wafer.

(Working Examples)

The following describes the working examples of the invention as set forth herein. The following working examples are shown as examples of the nitride semiconductor wafer relating to the present invention. The present invention is not limited by the following working examples.

According to one working example, a nitride semiconductor wafer was manufactured and used to fabricate an LED element. Specifically speaking, on a sapphire substrate having a thickness of 650 μm and a diameter of 100 mm, an aluminum nitride (AlN) layer of 150 nm was grown at high temperature as a buffer layer using HYPE. After this, an n-type gallium nitride (GaN) layer of 8 μm was grown as a nitride semiconductor layer, which was to serve as a template layer. In this way, a template was fabricated. On the template, as a light emitting section, an n-type GaN layer (having a thickness t₁), an InGaN/GaN light emitting layer having a multiple quantum well structure (having a thickness of 78 nm), and a p-type nitride semiconductor layer (having a thickness of 300 nm) constituted by a p-type AlGaN layer and a p-type GaN contact layer were regrown using MOVPE. In this manner, a nitride semiconductor wafer was manufactured.

According to first to fifth working examples and first and second comparative examples, nitride semiconductor wafers were manufactured in such a manner that the maximum value of the growth temperature T_{MAX} was set at various values for the regrowth of the light emitting section and the thickness t₁ was set at various values when the regrowth was performed at each of the values of the maximum value of the growth temperature T_{MAX}. On the manufactured nitride semiconductor wafers, electrodes were formed and other treatments were performed to fabricate LED elements, and the light emitted by the LED elements when applied with 20 mA was measured. In order to evaluate the light emitted from these LED elements, the ratio of the light emitted from each of the LED elements of the first to fifth working examples and the first and second comparative examples when 20 mA was applied to the light emitted from the LED element having the same structure but manufactured using the continuous growth technique when 20 mA was applied was calculated. In addition, the minimum distance tₘᵢₙ was determined that can result in a ratio of approximately 50% or does not cause the drop in the light emission characteristics of the LED elements.

In the first working example, T_{MAX}=820° C. and tₘᵢₙ=240 nm. In the second working example, T_{MAX}=890° C. and tₘᵢₙ=350 nm. In the third working example, T_{MAX}=950° C. and tₘᵢₙ=500 nm. In the fourth working example, T_{MAX}=980° C. and tₘᵢₙ=800 nm. In the fifth working example, T_{MAX}=1020° C. and t_{MAX}=1000 nm. In the first comparative example, T_{MAX}=1050° C. and tₘᵢₙ=1400 nm. In the second comparative example, T_{MAX}=1120° C. and tₘᵢₙ=2000 nm.

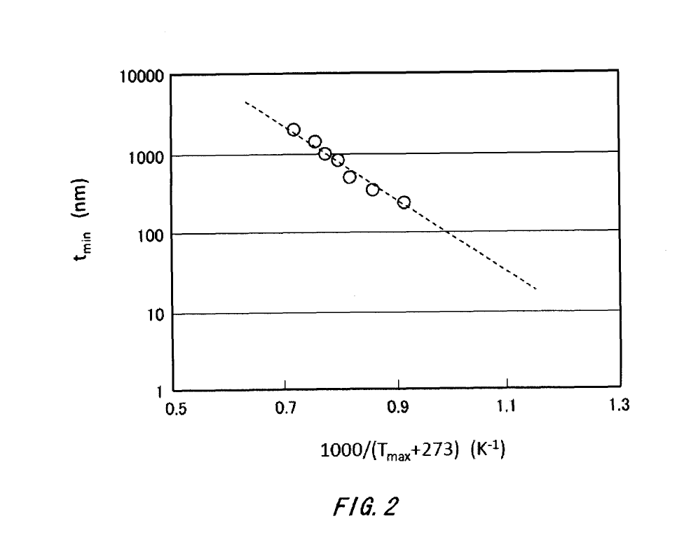

FIG. 2 shows the measured data. The logarithmic values of tₘᵢₙ [nm] are plotted along the vertical axis y, and the values of 1000/(T_{MAX}+273) [K⁻¹] are plotted along the horizontal axis x. FIG. 2 shows an Arrhenius plot. The plot is approximated by the linear line, which is shown as the dotted line in FIG. 2. The gradient of the linear line determines the above-described barrier energy (activation energy) Eₐ necessary for the oxygen atoms to diffuse, and the y-intercept determines the constant for the diffusion distance. To be specific, the linear line in FIG. 2 expresses the following. tₘᵢₙ=3.682×10⁶ ×exp{−Eₐ/k(T_{MAX}+273)}, where Eₐ =0.915 [eV](=0.951×1.6×10⁻¹⁹ [J]) and k denotes the Boltzmann's constant (k=1.38×10⁻²³ [J·K⁻¹]). As is apparent from FIG. 2, there is high correlation between the distance tₘᵢₙ and the maximum value of the growth temperature T_{MAX}. For example, the distance tₘᵢₙ can be reliably obtained based on the maximum value of the growth temperature T_{MAX}.

While the embodiments of the present invention have been described, the technical scope of the invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

### DESCRIPTION OF REFERENCE NUMERALS

1 . . . nitride semiconductor wafer
10 . . . template
11 . . . substrate
12 . . . nitride semiconductor layer
20 . . . light emitting section
21 . . . n-type nitride semiconductor layer
22 . . . light emitting layer
23 . . . p-type nitride semiconductor layer
24 . . . well layer
24′ . . . top well layer

What is claimed is:

1. A nitride semiconductor wafer in which, above a nitride semiconductor template having a nitride semiconductor layer as a top layer thereof, a light emitting layer having a multiple quantum well structure that is formed by a regrown nitride semiconductor and a p-type nitride semiconductor layer are stacked, wherein
when the light emitting layer having a multiple quantum well structure includes a plurality of well layers and one of the well layers that is the closest to the p-type nitride semiconductor layer is referred to as a top well layer,
a distance t from a regrowth interface of the nitride semiconductor layer of the nitride semiconductor template to the top well layer is 1 μm or less, and
the top well layer has an oxygen concentration of 5.0×10¹⁶ cm⁻³ or less.

2. The nitride semiconductor wafer as set forth in claim 1, wherein the distance t is 500 μm or less.

3. The nitride semiconductor wafer as set forth in claim 1, further comprising an n-type nitride semiconductor layer between the nitride semiconductor layer and the light emitting layer having a multiple quantum well structure.

4. The nitride semiconductor wafer as set forth in claim 1, wherein the light emitting layer having a multiple quantum well structure is positioned immediately above the nitride semiconductor layer.

5. A method of manufacturing a nitride semiconductor wafer in which, above a nitride semiconductor template having a nitride semiconductor layer as a top layer thereof, a light emitting layer having a multiple quantum well structure that is formed by a regrown nitride semiconductor and a p-type nitride semiconductor layer are stacked, the method comprising
above the nitride semiconductor layer of the nitride semiconductor template, regrowing in order the light emitting layer having a multiple quantum well structure and the p-type nitride semiconductor layer, wherein
when the light emitting layer having a multiple quantum well structure includes a plurality of well layers and one of the well layers that is the closest to the p-type nitride semiconductor layer is referred to as a top well layer,
the regrowing is performed in such a manner that a distance t [nm] from a regrowth interface of the nitride semiconductor layer of the nitride semiconductor template to the top well layer and a maximum value of a growth temperature T_{MAX} [° C.] for the regrowing satisfy a relation expressed by t≧3.682×10⁶ ×exp{−Eₐ/k(T_{MAX}+273)} and the distance t is 1 μm or less, where Eₐ is set to 0.915 [eV] and k denotes the Boltzmann's constant.
